(19) United States
(12) Patent Application Publication
(10) Pub. No.: US 2010/0078780 A1
(43) Pub. Date: Apr. 1, 2010

(54) Semiconductor device

(75) Inventors: Yuichi Nakao, Kyoto (JP); Ryosuke Nakagawa, Kyoto (JP)

Correspondence Address: RABIN & Berdo, PC, 1101 14TH STREET, NW, SUITE 500, WASHINGTON, DC, 20005, US

(73) Assignee: ROHM CO., LTD., Kyoto (JP)

(21) Appl. No.: 12/585,837

(22) Filed: Sep. 25, 2009

(30) Foreign Application Priority Data
Sep. 26, 2008 (JP) 2008-248902

(51) Int. Cl. H01L 23/52; H01L 23/552

(52) U.S. Cl. 257/659; 257/751; 257/E23.141; 257/E23.114

(57) ABSTRACT

A semiconductor device according to the present invention includes: a wiring; an interlayer insulating film formed over the wiring and having an opening reaching the wiring from a top surface thereof; an intra-opening metal film formed on the wiring inside the opening and made of a metal material that contains aluminum; a top surface metal film formed over the interlayer insulating film and made of the metal material; and a conduction securing film formed on a side surface of the opening to secure conduction between the intra-opening metal film and top surface metal film.

### BACKGROUND OF THE INVENTION

1. Field of the Invention

The present invention relates to a semiconductor device and particularly to a power semiconductor device.

2. Description of the Related Art

Recently, in the field of power electronics, power semiconductor devices that include a transformer (hereinafter referred to as “transformer devices”) have been developed.

FIG. 3 is a schematic sectional view of a transformer device.

The transformer device 101 includes a first insulating layer 102 made of SiO₂ (silicon oxide) on a semiconductor substrate not shown.

A first wiring groove 103 is formed in the first insulating layer 102. A first wiring 105, formed of a metal material having Cu (copper) as a main component (hereinafter referred to as the “Cu wiring material”), is embedded via a barrier metal 104 in the first wiring layer 103.

A second insulating layer 106 is laminated on the first insulating layer 102. The second insulating layer 106 has a structure where a diffusion preventing/etching stopper film 107, an interlayer insulating film 108, an etching stopper film 109, and an insulating film 110 are laminated in that order.

A second wiring groove 111 is formed in the second insulating layer 106. The second wiring groove 111 is formed by digging in from an upper surface of the insulating film 110 to an upper surface of the interlayer insulating film 108. A second wiring 113, formed of the Cu wiring material, is embedded via a barrier metal 112 in the second wiring groove 111.

Also, the second wiring groove 111 is formed in a pattern having a portion that intersects the first wiring 105 in plan view. At the portion at which the first wiring 105 and the second wiring groove 111 intersect in plan view, a via hole 114, which penetrates through the diffusion preventing/etching stopper film 107 and the interlayer insulating film 108, is formed between the first wiring 105 and the second wiring groove 111. A via 116 is embedded via a barrier metal 115 in the via hole 114. The first wiring 105 and the second wiring 113 are thereby electrically connected via the via 116.

A coil groove 117 having a spiral form in plan view and having the same depth as the second wiring groove 111 is formed spaced apart by an interval from the second wiring groove 111 in the second insulating layer 106. A coil 119, which makes up a transformer, is embedded via a barrier metal 118 in the coil groove 117.

A diffusion preventing/etching stopper film 120 and an interlayer insulating film 121 are laminated on the second insulating layer 106. The second wiring 113 is an uppermost layer wiring, and a pad opening 122, reaching the second wiring 113 from a top surface of the interlayer insulating film 121, is formed in the diffusion preventing/etching stopper film 120 and the interlayer insulating film 121. A barrier metal 123 is coated on inner surfaces of the pad opening 122. A bonding pad 124, formed of an alloy containing Al (aluminum) and Cu (hereinafter referred to as the “AlCu alloy”), is provided on the barrier metal 123 inside the pad opening 122. A bonding wire (not shown) for electrical connection with an exterior is connected to the bonding pad 124.

The barrier metal 123 is also formed selectively on the interlayer insulating film 121 outside the pad opening 122. That is, the barrier metal 123 is formed continuously on the inner surfaces of the pad opening 122 and a region on the interlayer insulating film 121 lying outside the pad opening 122 and opposing the coil 119. An electromagnetic shielding film 125, made of the same material as the bonding pad 124, is formed on the barrier metal 123 formed on the region opposing the coil 119.

In forming the barrier metal 123, the bonding pad 124, and the electromagnetic shielding film 125, first, a film made of the material of the barrier metal 123 is formed across an entirety of the inner surfaces of the pad opening 122 and the top surface of the interlayer insulating film 121 by sputtering. Next, a film made of the AlCu alloy (AlCu alloy film) is then formed on the film made of the material of the barrier metal 123 by sputtering. The AlCu alloy film and the film made of the material of the barrier metal 123 on the top surface of the interlayer insulating film 121 are then selectively removed (patterned) to obtain the barrier metal 123, the bonding pad 124, and the electromagnetic shielding film 125.

In the patterning of the AlCu alloy film, the AlCu alloy remains on a side surface of the pad opening 122. The bonding pad 124 and the electromagnetic shielding film 125 are electrically connected by the remaining AlCu alloy, and the electromagnetic shielding film 125 thereby exhibits a function of shielding electromagnetic waves generated from the coil 119.

To secure a withstand voltage between the coil 119 and the electromagnetic shielding film 125, the interlayer insulating film 121 has a thickness of not less than 2 to 3 μm. Thus, the pad opening 122 has a size in a depth direction of not less than 2 to 3 μm and a size in a lateral direction (direction orthogonal to the depth direction) of not less than 10 μm and normally approximately 100 μm. Coverage of the side surface of the pad opening 122 by the AlCu alloy film is thus poor, and a conduction failure may occur between the bonding pad 124 and the electromagnetic shielding film 125.

A method where, after completely filling the interior of the pad opening 122 with the Cu wiring material, etc., the AlCu alloy film is formed on the interlayer insulating film 121 and the pad opening 122 and this film is patterned to form the bonding pad 124 and the electromagnetic shielding film 125 may be considered. However, with this method, once the AlCu alloy film is formed, it is extremely difficult to align (position) a mask in a photolithography process for patterning the AlCu alloy because the substrate (the Cu wiring material inside the pad opening 122) is hidden by the AlCu alloy film and the top surface of the AlCu alloy film is a flat surface.

### SUMMARY OF THE INVENTION

An object of the present invention is to provide a semiconductor device with which conduction between a bonding pad or other intra-opening metal film and a surface metal film on an interlayer insulating film can be secured.

A semiconductor device according to one aspect of the present invention includes: a wiring; an interlayer insulating film formed over the wiring and having an opening reaching the wiring from a top surface thereof; an intra-opening metal film formed on the wiring inside the opening and made of a metal material that contains aluminum; a top surface metal film formed over the interlayer insulating film and made of the metal material; and a conduction securing film formed (at least) on a side surface of the opening to secure conduction between the intra-opening metal film and top surface metal film.

By this configuration, the opening that reaches the wiring from the top surface of the interlayer insulating film is formed in the interlayer insulating film over the wiring. The intra-opening metal film, made of the metal material that contains aluminum, is formed on the portion of the wiring that faces the opening. Further, the top surface metal film made of the same metal material as the intra-opening metal film is formed over the interlayer insulating film. Then, the conduction securing film for securing the conduction between the intra-opening metal film and the top surface metal film is formed on the side surface of the opening.

In a case of adopting a method where a film made of the metal material that contains aluminum is formed by sputtering and the intra-opening metal film and the top surface metal film are formed by patterning this film, if the metal material is deposited satisfactorily on the side surface of the opening, electrical connection (conduction) between the intra-opening metal film and the top surface metal film is achieved via the metal material deposited on the side surface. Even if the metal material is not deposited satisfactorily on the side surface of the opening and coverage failure of the metal material (film) with respect to the side surface of the opening occurs, the conduction between the intra-opening metal film and the top surface metal film can be secured by the conduction securing film.

The conduction securing film is preferably formed by CVD (chemical vapor deposition). By CVD, a material of the conduction securing film can be deposited satisfactorily on the side surface of the opening and the conduction securing film can be formed reliably on the side surface of the opening.

The material of the conduction securing film may be tungsten.

Preferably, the conduction securing film has a thickness of not more than 100 nm and not less than the thickness of the interlayer insulating film. In this case, a thickness enabling a satisfactory conduction (low resistance connection) to be secured between the intra-opening metal film and the top surface metal film is provided and at the same time, a step is formed at the top surface of the conduction securing film and this step can be used to align a mask for patterning in a photolithography process for forming the top surface metal film.

The metal material that is the material of the intra-opening metal film and the top surface metal film may be an AlCu alloy that contains aluminum and copper.

The semiconductor device may further include a barrier metal interposed between the interlayer insulating film and the top surface metal film to prevent diffusion of a component of the metal material into the interlayer insulating film.

The semiconductor device may further include a coil formed in the same layer as the wiring and having a spiral form in plan view for making up a transformer. In this case, the top surface metal film may be an electromagnetic shielding film that covers and hides the coil in plan view to shield electromagnetic waves from an exterior to prevent erroneous operation.

The intra-opening metal film may be a bonding pad to which a bonding wire for electrical connection with the exterior is connected.

The foregoing and other objects, features and effects of the present invention will become more apparent from the following detailed description of the embodiments with reference to the attached drawings.

### BRIEF DESCRIPTION OF THE DRAWINGS

FIG. 1 is a schematic sectional view of a semiconductor device according to an embodiment of the present invention.

FIGS. 2A to 2G are schematic sectional views illustrating a manufacturing process of the semiconductor device in successive order.

FIG. 3 is a schematic sectional view of a conventional transformer device.

### DETAILED DESCRIPTION OF THE PREFERRED EMBODIMENT(S)

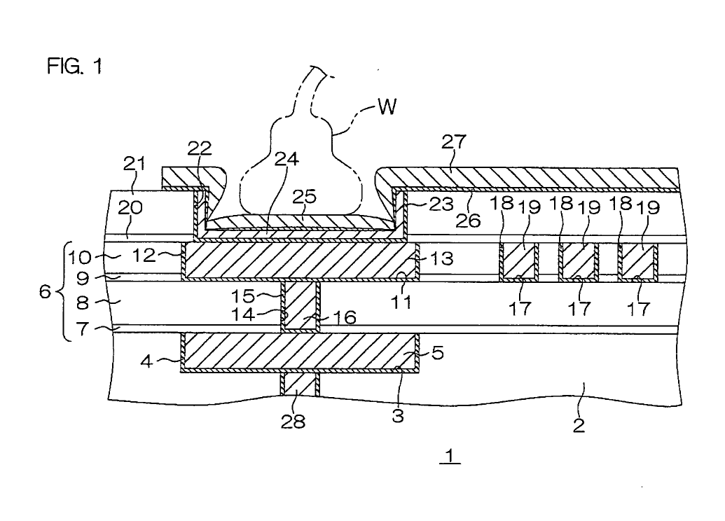

FIG. 1 is a schematic sectional view of a semiconductor device according to an embodiment of the present invention.

The semiconductor device 1 is a transformer device and includes an unillustrated semiconductor substrate. An Si (silicon) substrate, an SiC (silicon carbide) substrate, etc., can be cited as examples of the semiconductor substrate.

A first insulating layer 2 is laminated on the semiconductor substrate. The first insulating layer 2 is made, for example, of SiO₂.

A first wiring groove 3 is formed in the first insulating layer 2. The first wiring groove 3 has a recessed form formed by digging in from an upper surface of the first insulating layer 2.

A barrier metal 4 is formed on inner surfaces (a side surface and a bottom surface) of the first wiring groove 3. The barrier metal 4 has a structure where, for example, a Ta (tantalum) film, a TaN (tantalum nitride) film, and a Ta film are laminated in that order from the bottom. Then, a first wiring 5, made of a Cu wiring material (a metal material having Cu as a main component), is embedded via the barrier metal 4 in the first wiring groove 3. A top surface of the first wiring 5 is flush with a top surface of the first insulating layer 2. The barrier metal 4 prevents a component contained in the Cu wiring material of the first wiring 5 from diffusing into the first insulating layer 2.

A second insulating layer 6 is laminated on the first insulating layer 2. The second insulating layer 6 has a structure where a diffusion preventing/etching stopper film 7, an interlayer insulating film 8, an etching stopper film 9, and an insulating film 10 are laminated in that order. The diffusion preventing/etching stopper film 7 and the etching stopper film 9 are made, for example, of SiN (silicon nitride). The interlayer insulating film 8 and the insulating film 10 are made, for example, of SiO₂. The diffusion preventing/etching stopper film 7 prevents a component contained in the Cu wiring material of the first wiring 5 from diffusing into the first insulating layer 2.

A second wiring groove 11 is formed on a top layer portion of the second insulating layer 6. The second wiring groove 11 has a recessed form formed by digging in from an upper surface of the insulating film 10 to an upper surface of the interlayer insulating film 8.

A barrier metal 12 is formed on inner surfaces (a side surface and a bottom surface) of the second wiring groove 11. The barrier metal 12 has a structure where a Ta film, a TaN film, and a Ta film are laminated in that order from the bottom. Then, a second wiring 13, made of the Cu wiring material, is embedded via the barrier metal 12 in the second wiring groove 11. The second wiring 13 has a top surface that is flush with a top surface of the second insulating layer 6 and has a thickness (for example, of 2 μm) equivalent to subtracting a thickness of the barrier metal 12 from a depth of the second wiring groove 11. The barrier metal 12 prevents a component contained in the Cu wiring material of the second wiring 13 from diffusing into the second insulating layer 6.

The second wiring groove 11 is formed in a pattern having a portion that intersects the first wiring 5 in plan view. Then, at the portion at which the first wiring 5 and the second wiring groove 11 intersect in plan view, a via hole 114, which penetrates through the diffusion preventing/etching stopper film 7 and the interlayer insulating film 8, is formed between the first wiring 5 and the second wiring groove 111.

A barrier metal 15 is formed on a side surface of the via hole 14 and on a portion of the first wiring 5 that faces the via hole 14. The barrier metal 15 has a structure where a Ta film, a TaN film, and a Ta film are laminated in that order from the bottom. Then, a via 16, made of a Cu wiring material, is embedded via the barrier metal 15 in the via hole 14. The barrier metal 15 prevents a component contained in the Cu wiring material of the via 16 from diffusing into the second insulating layer 6. The first wiring 5 and the second wiring 13 are electrically connected via the via 16.

A coil groove 17 having a spiral form in plan view and having the same depth as the second wiring groove 11 is formed spaced apart by an interval from the second wiring groove 11 in the same layer as the second wiring groove 11 in the second insulating layer 6.

A barrier metal 18 is formed on inner surfaces (a side surface and a bottom surface) of the coil groove 17. The barrier metal 18 has the same laminated structure as the barrier metal 12 formed on the inner surfaces of the second wiring groove 11. That is, the barrier metal 18 has the structure where the Ta film, the TaN film, and the Ta film are laminated in that order from the bottom. Then, a coil 19, made of the Cu wiring material that is the same material as the material of the second wiring 13, is embedded via the barrier metal 18 in the coil groove 17. The coil 19 makes up a transformer together with another coil (not shown). The coil 19 has a top surface that is flush with the top surface of the second insulating layer 6 and has the same thickness as the second wiring 13. The barrier metal 18 prevents a component contained in the Cu wiring material of the coil 19 from diffusing into the second insulating layer 6.

A diffusion preventing/etching stopper film 20 and an interlayer insulating film 21 are laminated on the second insulating layer 6. The diffusion preventing/etching stopper film 20 is made, for example, of SiN and has a thickness of 100 nm. The interlayer insulating film 21 is made, for example, of SiO₂ and has a thickness of 2.4 μm. The diffusion preventing/etching stopper film 20 prevents a component contained in the Cu wiring material of the second wiring 13 from diffusing into the interlayer insulating film 21.

The second wiring 13 is an uppermost layer wiring and a pad opening 22, reaching the second wiring 13 from a top surface of the interlayer insulating film 21, is formed in the diffusion preventing/etching stopper film 20 and the interlayer insulating film 21. A side surface of the pad opening 22 is formed by the diffusion preventing/etching stopper film 20 and the interlayer insulating film 21. A size in a lateral direction (direction orthogonal to the depth direction) of the pad opening 22 is, for example, 100 μm.

A barrier metal 23 is formed on the side surface of the pad opening 22 and on a portion of the second wiring 13 that faces the pad opening 22. The barrier metal 23 has a structure where a Ta film, a TaN film, a Ti (titanium) film, and a TiN film are laminated in that order from the bottom. The thicknesses of the Ta film, TaN film, Ti film, and TiN film are, for example, 7.5 μm, 7.5 μm, 20 μm, and 10 μm, respectively.

A conduction securing film 24, made of W (tungsten) is formed on the barrier metal 23. Inside the pad opening 22, the conduction securing film 24 covers the entire top surface of the barrier metal 23. The conduction securing film 24 has a thickness, for example, of 200 to 400 nm (0.2 to 0.4 μm). Thus, the interior of the pad opening 22 is not completely filled by the conduction securing film 24. The barrier metal 23 prevents the W contained in the material of the conduction securing film 24 from diffusing into the second insulating layer 6.

Inside the pad opening 22, a bonding pad 25, made of an AlCu alloy (an alloy containing Al and Cu), is formed above the second wiring 13 across the barrier metal 23 and the conduction securing film 24. A bonding wire (not shown) for electrical connection with an exterior is connected to the bonding pad 25.

On the interlayer insulating film 21, a barrier metal 26 is formed in a region opposing an entirety of the coil 19 and a circumferential region of the pad opening 22. The barrier metal 26 is also formed on the conduction securing film 24. The barrier metal 26 has a structure where a Ti film and a TiN film are laminated in that order from the bottom. The thicknesses of the Ti film and the TiN film are, for example, 7 nm (0.007 μm) and 40 nm (0.04 μm), respectively.

An electromagnetic shielding film 27, made of the AlCu alloy that is the same material as the material of the bonding pad 25, is formed on the barrier metal 26. The electromagnetic shielding film 27 has a thickness, for example, of 900 nm (0.9 μm). The electromagnetic shielding film 27 is formed so as to wrap around the side surface of the pad opening 22 and is connected directly to the bonding pad 25 or is electrically connected to the bonding pad 25 via the conduction securing film 24. The electromagnetic shield film 27 thus covers and hides the coil 19 in plan view and shields electromagnetic waves from the exterior to prevent erroneous operation. Also, the barrier metal 26 prevents a component contained in the material of the electromagnetic shielding film 27 from diffusing into the second insulating layer 6.

In addition, one or a plurality of insulating layers may be interposed between the semiconductor substrate and the first insulating layer 2, and another wiring may be formed at a layer below the first wiring 5. In this case, the first wiring 5 is electrically connected to the wiring at the layer below the first wiring 5 via a via 28. Obviously, the first insulating layer 2 may be formed to be in contact with the semiconductor substrate and the first wiring 5 may be a lowermost layer wiring.

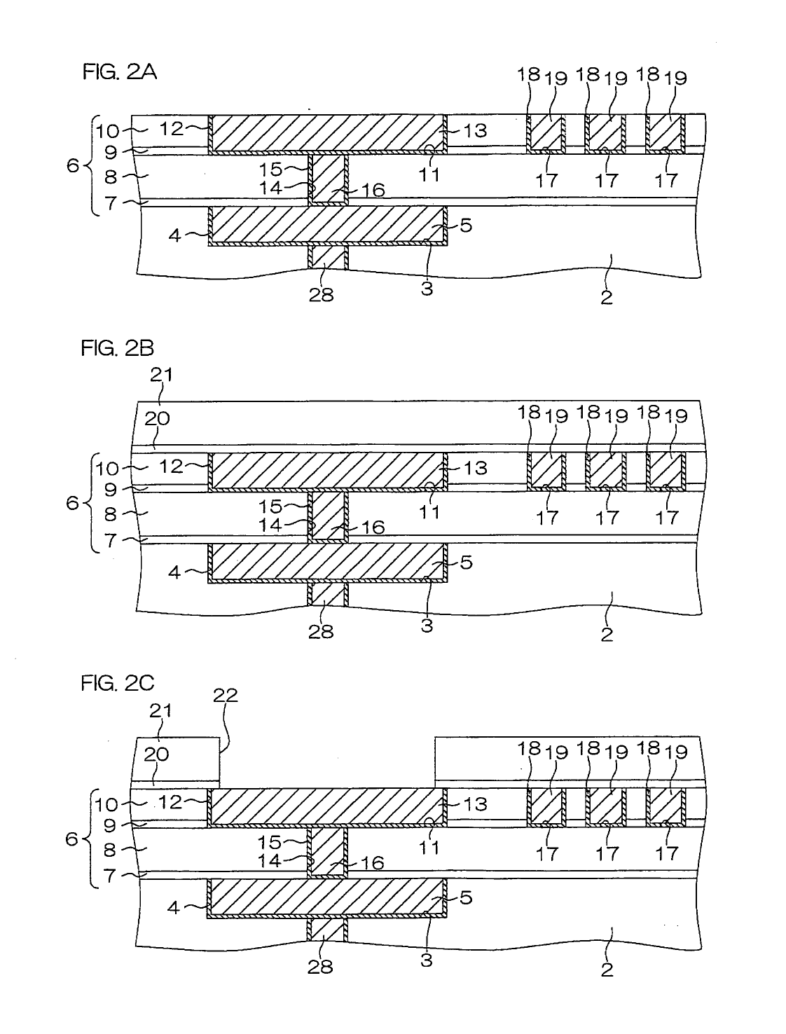

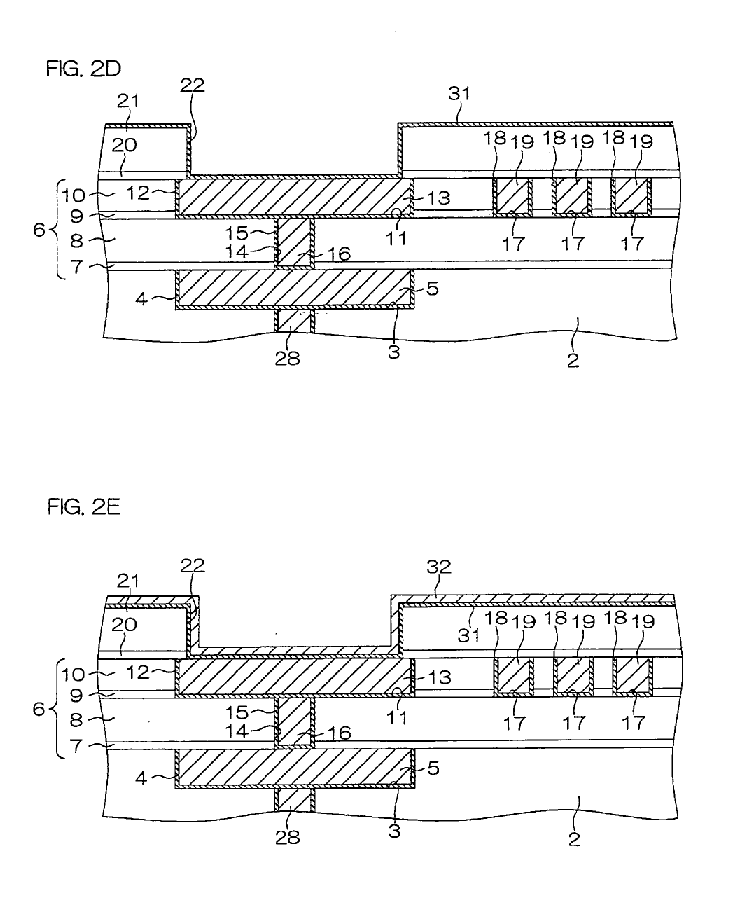

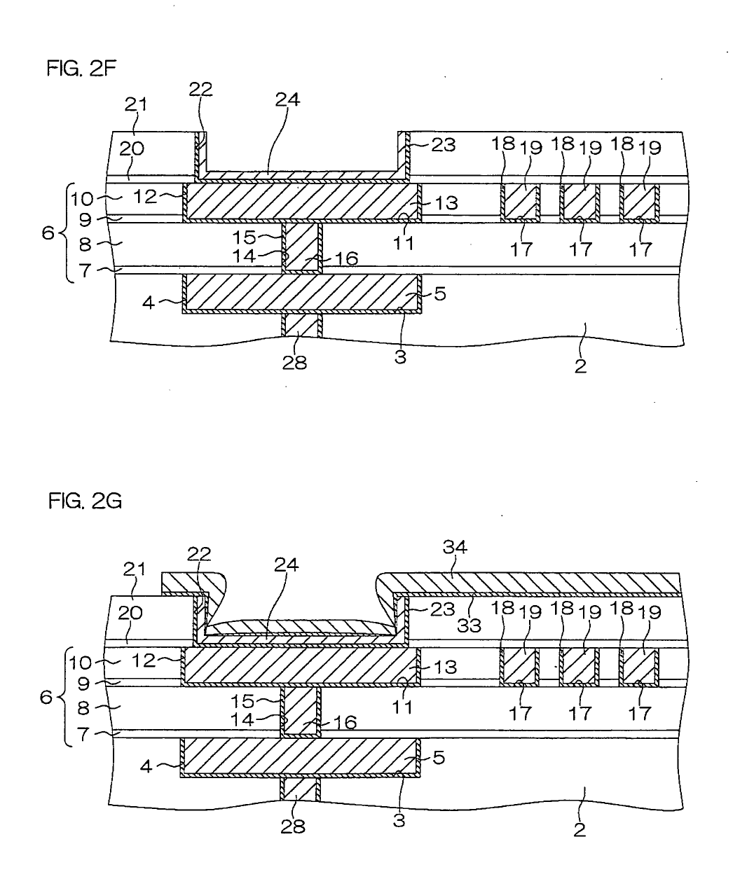

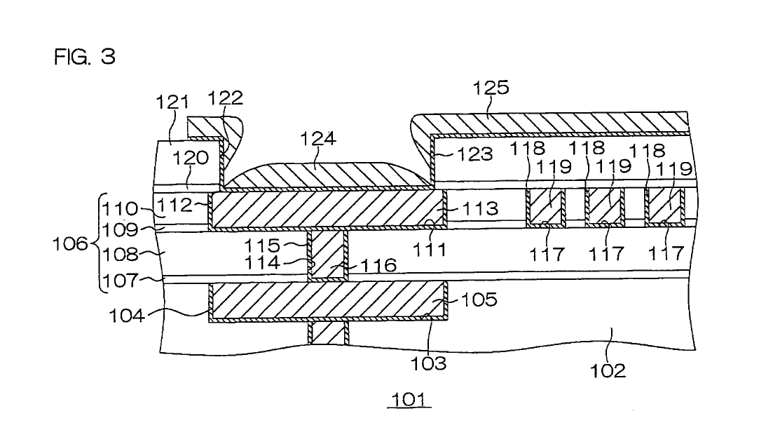

FIGS. 2A to 2G are schematic sectional views for describing a manufacturing process of the semiconductor device shown in FIG. 1.

As shown in FIG. 2A, the first insulating layer 2, the first wiring groove 3, the barrier metal 4, the first wiring 5, the second insulating layer 6, the second wiring groove 11, the barrier metal 12, the second wiring 13, the via hole 14, the barrier metal 15, the via 16, the coil groove 17, the barrier metal 18, and the coil 19 are formed by a known method (for example, a method including a single damascene method).

As shown in FIG. 2B, the diffusion preventing/etching stopper film 20 and the interlayer insulating film 21 are formed successively on the second insulating layer 6 by PECVD (plasma enhanced chemical vapor deposition).

Next, as shown in FIG. 2C, the pad opening 22 is formed by photolithography and etching.

Thereafter, as shown in FIG. 2D, a laminated film (for example, a Ta film, a TaN film, a Ti film, and a TiN film) 31, made of the materials of the barrier metal 23, is formed on the side surface of the pad opening 22 and the portion of the second wiring 13 that faces the pad opening 22 by sputtering.

Next, as shown in FIG. 2E, a W film 32, made of W, is formed on the laminated film 31 by CVD.

A top surface of the W film 32 is then polished by a CMP (chemical mechanical polishing) method. As shown in FIG. 2F, this polishing is kept until a portion of the W film 32 outside the pad opening 22 is eliminated completely and further, a portion of the laminated film 31 outside the pad opening 22 is eliminated completely and furthermore, the upper surface of the interlayer insulating film 21 is exposed outside the pad opening 22. The barrier metal 23 and the conduction securing film 24 are thereby obtained in the pad opening 22.

Thereafter, as shown in FIG. 2G, a laminated film (for example, a Ti film and a TiN film) 33, made of the material of the barrier metal 26, is formed on the interlayer insulating film 21 by sputtering. Next, an AlCu alloy film 34, made of the AlCu alloy, is formed on the barrier metal 26 by sputtering.

Thereafter, the laminated film 33 and the AlCu alloy film 34 are patterned by photolithography and etching. Consequently, the bonding pad 25, the barrier metal 26, and the electromagnetic shielding film 27 are formed and the semiconductor device 1 that includes these is obtained as shown in FIG. 1.

As described above, the pad opening 22, reaching the second wiring 13 from the top surface of the interlayer insulating film 21, is formed in the interlayer insulating film 21 on the second wiring 13. The bonding pad 25, made of the AlCu alloy, is formed on the portion of the second wiring 13 that faces the pad opening 22. Further, the electromagnetic shielding film 27, made of the AlCu alloy that is the same material as the material of the bonding pad 25, is formed over the interlayer insulating film 21. The conduction securing film 24, for securing conduction between the bonding pad 25 and the electromagnetic shielding film 27, is formed on the side surface of the pad opening 22.

Even if during the forming of the AlCu alloy film 34 by sputtering, the AlCu alloy is not deposited satisfactorily on the side surface of the pad opening 22 and a coverage failure of the AlCu alloy film 34 with respect to the side surface of the pad opening 22 occurs, the conduction between the bonding pad 25 and the electromagnetic shielding film 27 can be secured by the conduction securing film 24.

The conduction securing film 24 is formed by forming the W film 32 by CVD and then eliminating the W film 32 outside the pad opening 22. The W film 32 can be deposited satisfactorily on the side surface of the pad opening 22 by CVD. Consequently, the conduction securing film 24 can be formed reliably on the side surface of the pad opening 22.

In addition, the elimination of the W film 32 outside the pad opening 22 is not restricted to the CMP method and may be achieved by etch back instead. In this case, the conduction securing film 24 is formed just on the side surface of the pad opening 22 and does not have to be formed between the barrier metal 23 and the bonding pad 25. That is, it suffices that the conduction securing film 24 be formed at least on the side surface of the pad opening 22.

Although the thickness of the conduction securing film 24 was stated as being 200 to 400 nm, for example, the thickness is not restricted to this range. However, the thickness of the conduction securing film 24 (W film 32) is preferably not less than 100 nm and not more than the thickness of the interlayer insulating film 21. With such a thickness, a thickness enabling a satisfactory conduction (low resistance connection) to be secured between the bonding pad 25 and the electromagnetic shielding film 27 is provided and at the same time, a step is formed at the top surface of the conduction securing film 24 and this step can be used to align a mask for patterning in a photolithography process for forming the electromagnetic shielding film 27.

Further, although it was described that the conduction securing film 24 is made of W, the material of the conduction securing film 24 is not restricted to W, and Cu or TiN, etc., may be used instead. In a case where Cu is adopted, a layer to serve as a basis of the conduction securing film 24 can be formed by CVD. In a case where TiN is adopted, a layer to serve as a basis of the conduction securing film 24 can be formed by sputtering.

While the present invention has been described in detail by way of the embodiments thereof, it should be understood that these embodiments are merely illustrative of the technical principles of the present invention but not limitative of the invention. The spirit and scope of the present invention are to be limited only by the appended claims.

This application corresponds to Japanese Patent Application No. 2008-248902 filed with the Japan Patent Office on Sep. 26, 2008, the disclosure of which is incorporated herein by reference.

What is claimed is:

1. A semiconductor device comprising:
a wiring;
an interlayer insulating film formed over the wiring and having an opening reaching the wiring from a top surface thereof;
an intra-opening metal film formed on the wiring inside the opening and made of a metal material that contains aluminum;
a top surface metal film formed over the interlayer insulating film and made of the metal material; and
a conduction securing film formed on a side surface of the opening to secure conduction between the intra-opening metal film and the top surface metal film.

2. The semiconductor device according to claim 1, wherein
the conduction securing film is formed by CVD.

3. The semiconductor device according to claim 1, wherein
the conduction securing film is made of tungsten.

4. The semiconductor device according to claim 1, wherein
the conduction securing film has a thickness of not less than 100 nm and not more than the thickness of the interlayer insulating film.

5. The semiconductor device according to claim 1, wherein the metal material is an AlCu alloy that contains aluminum and copper.

6. The semiconductor device according to claim 1, further comprising:
a barrier metal interposed between the interlayer insulating film and the top surface metal film to prevent diffusion of a component of the metal material into the interlayer insulating film.

7. The semiconductor device according to claim 1, further comprising:
a coil formed in the same layer as the wiring and having a spiral form in plan view for making up a transformer; and
wherein the top surface metal film is an electromagnetic shielding film that covers a region opposing the coil in plan view to shield electromagnetic waves from an exterior.

8. The semiconductor device according to claim 1, wherein
the intra-opening metal film is a bonding pad to which a bonding wire for electrical connection with an exterior is connected.
